(19) United States
(12) Patent Application Publication
(10) Pub. No.: US 2020/0186684 A1
(43) Pub. Date: Jun. 11, 2020

(54) CIRCUIT BOARD ASSEMBLY, CAMERA MODULE, AND ELECTRONIC DEVICE INCLUDING THE SAME

(71) Applicant: TRIPLE WIN TECHNOLOGY(SHENZHEN) CO.LTD., Shenzhen (CN)

(72) Inventors: SHIN-WEN CHEN, ,New Taipei (TW); SHENG-JIE DING, Shenzhen (CN); JING-WEI LI, Shenzhen (CN); JIAN-CHAO SONG, Shenzhen (CN)

(21) Appl. No.: 16/547,841

(22) Filed: Aug. 22, 2019

(30) Foreign Application Priority Data
Dec. 11, 2018 (CN) 201822080959.7

(51) Int. Cl. H04N 5/225; H05K 1/11; H05K 1/14; H05K 1/18

(52) U.S. Cl. CPC H04N 5/2253; H04N 5/2257; H05K 1/189; H05K 1/141; H05K 1/118

(57) ABSTRACT

A circuit board assembly for a twin-camera module to avoid any heat-induced misalignments in manufacture is disclosed, to improve the production yield of the camera module. The circuit board assembly comprises at least two daughter boards and at least one first flexible printed circuit board. Each of the flexible printed circuit boards connects to adjacent two of the daughter boards. The disclosure also provides the twin-camera module comprising the circuit board assembly, and an electronic device comprising the camera module.

### FIELD

The subject matter herein generally relates to a circuit board assembly, a camera module including the circuit board assembly, and an electronic device including the camera module.

### BACKGROUND

Double-camera modules generally include two cameras, a bracket, a lens, a voice coil motor, a plastic base, glass, an image sensor, and a circuit board. For convenience in manufacturing, the two cameras are both mounted on and electrically coupled to the circuit board. Two common types of circuit boards include printed circuit boards and ceramic substrates. To save manufacturing cost, the printed circuit board is selected to function as the circuit board of the double-camera. However, in manufacturing, the printed circuit board may be bent or deformed after soldering elements onto the surface of the printed circuit board, and the positions of the optical axes of the cameras mounted on the printed circuit board may no longer match with the predetermined positions. Such a manufacturing processes affect the production yield and the imaging quality.

### BRIEF DESCRIPTION OF THE DRAWINGS

Implementations of the present technology will now be described, by way of embodiment, with reference to the attached figures.

FIG. 1 is an isometric view of an embodiment of a circuit board assembly.

FIG. 2 is similar to FIG. 1, but viewed from another angle.

FIG. 3 is an isometric view of an embodiment of a camera module.

FIG. 4 is an exploded view of the camera module of FIG. 3.

FIG. 5 is similar to FIG. 4, but viewed from another angle.

FIG. 6 is an isometric view of an embodiment of an electronic device.

FIG. 7 is a cross-sectional view of another embodiment of a circuit board assembly.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale and the proportions of certain parts may be exaggerated to better illustrate details and features of the present disclosure.

Several definitions that apply throughout this disclosure will now be presented.

The term “coupled” is defined as connected, whether directly or indirectly through intervening components, and is not necessarily limited to physical connections. The connection can be such that the objects are permanently connected or releasably connected. The term “substantially” is defined to be essentially conforming to the particular dimension, shape, or other feature that the term modifies, such that the component need not be exact. For example, “substantially cylindrical” means that the object resembles a cylinder, but can have one or more deviations from a true cylinder. The term “comprising,” when utilized, means “including, but not necessarily limited to”; it specifically indicates open-ended inclusion or membership in the so-described combination, group, series, and the like.

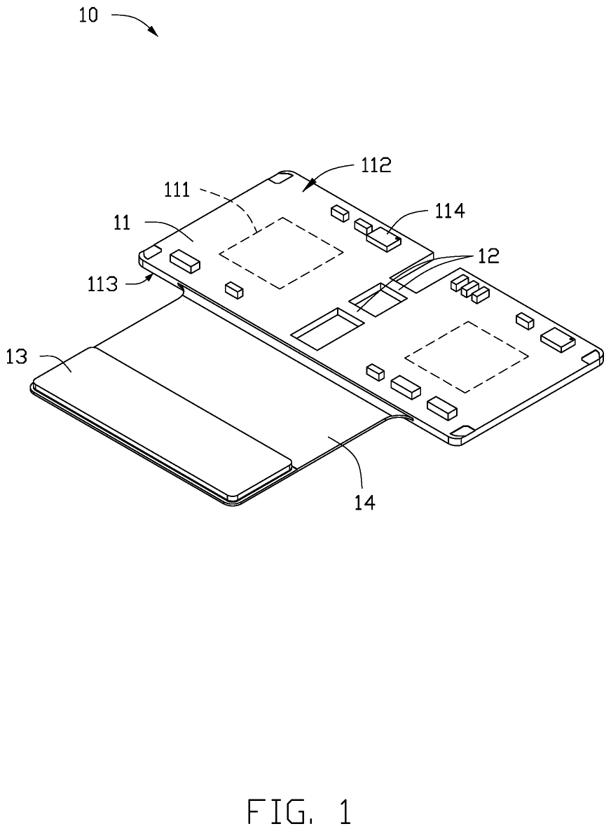

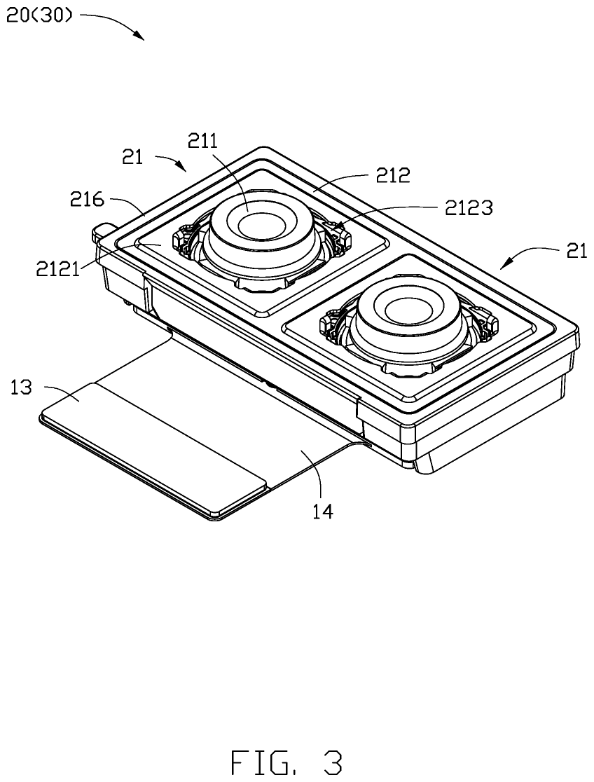

FIG. 1 illustrates a circuit board assembly 10 configured for carrying a camera module (shown in FIG. 3). The circuit board assembly 10 comprises at least two daughter boards 11 and at least one flexible printed circuit board 12. Each of the flexible printed circuit board 12 electrically connects to adjacent two of the daughter boards 11.

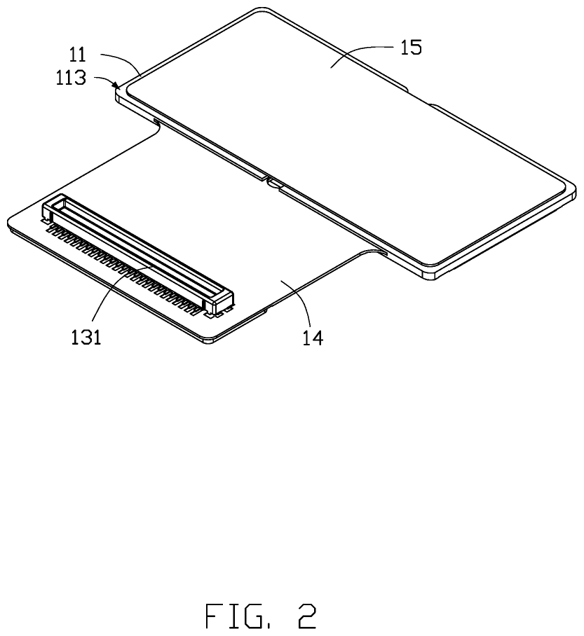

FIG. 2 illustrates that the circuit board assembly 10 further comprises a second flexible printed circuit board 14. The second flexible printed circuit board 14 is electrically connected to a side of the daughter boards 11. The second flexible circuit board 14 is provided with a connector 131. The connector 131 is connected with an external control circuit (not shown). The daughter boards 11 are electrically connected to the connector 13 by the second flexible printed circuit board 14, so as to be electrically connected to the external control circuit.

Compared with a single circuit board, the circuit board assembly 10 comprises a plurality of daughter boards spaced from each other, which reduces the deformation stress in high temperature soldering process, so as to avoid deformation of the circuit board assembly 10. Adjacent two of the daughter boards 11 are connected by the first flexible circuit board 12, thus the circuit layout of the original circuit board is not affected, and cost of the circuit layout is saved.

The daughter board 11 comprises a first surface 112 and a second surface 113 opposite to the first surface 112. The first surface 112 of the daughter board 11 defines a chip area 111, which carries an image sensor 215. A plurality of elements 114 for realizing the functions of the circuit board assembly 10 are arranged on the first surface 112.

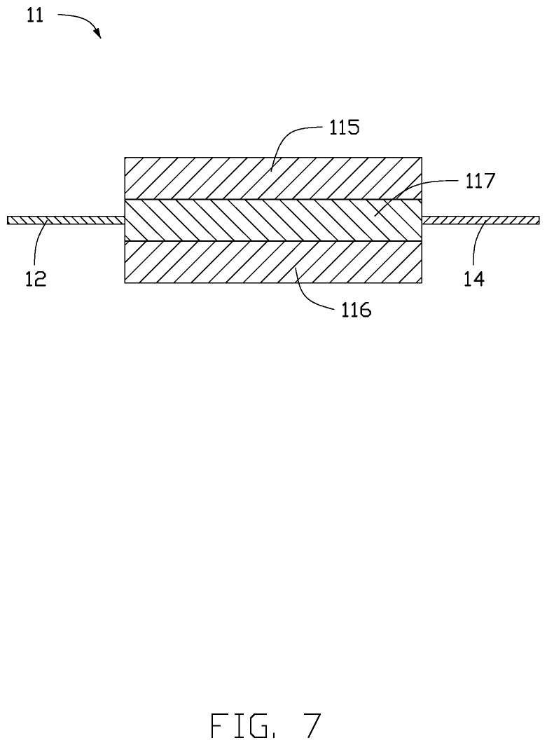

Furthermore, the daughter board 11 has a multilayered structure, the second flexible printed circuit board 14 is embedded into and pressed into the daughter board 11. In an alternative embodiment, FIG. 7 illustrates that the first flexible printed circuit board 12 can also be embedded into the daughter board 11. The daughter board 11 comprises a first hard board layer 115, a second hard board layer 116, and a flexible board layer 117 sandwiched between the first hard board layer 115 and the second hard board layer 116. The first flexible printed circuit board 12 and the second flexible printed circuit board 14 are separately connected to the flexible board layer 17.

The circuit board assembly 10 further comprises a connecting portion 13. The connecting portion 13 is fixed on a surface of the second flexible printed circuit board 14 away from the connector 131.

FIG. 2 illustrates that the circuit board assembly 10 further comprises a reinforcement plate 15. The reinforcement plate 15 is fixed on the second surfaces 113 of the daughter boards 11. Size of the reinforcement plate 15 is substantially the same as the sum of the size of the daughter boards 11 and the size of the first flexible printed circuit board 12. The reinforcement plate 15 can be a steel plate. The reinforcement plate 15 enhances the mechanical strength of the circuit board assembly 10, so bending and deformation in the process of high temperature soldering is much less likely.

In the process of high temperature soldering of the camera module 20, the temperature is up to 260° C.˜300° C., and the duration is from seconds to tens of seconds, so that the first hard board layer and the second hard board layer of the daughter board 11 are made of materials with high glass transition temperature Tg to further avoid the deformation of the circuit board assembly 10. In an alternative embodiment, the first hard board layer and the second hard board layer are made of polyphenylene oxide resin. The flexible board layer of the daughter board is a polymide film, a polyester film, or a combination thereof.

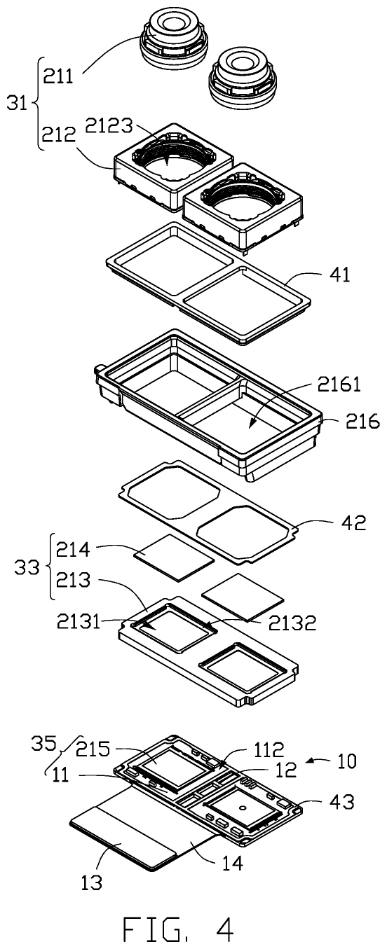

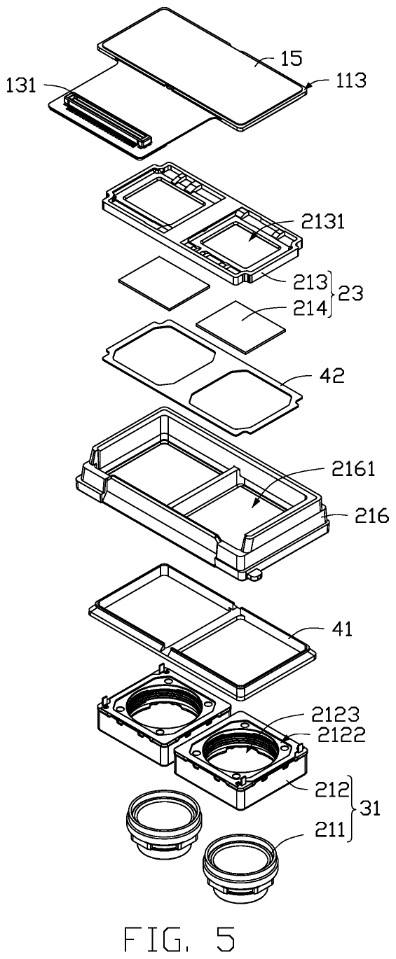

FIGS. 3 to 5 illustrate an embodiment of a camera module 20. The camera module 20 comprises at least two camera units 21 and the circuit board assembly 10. Each camera unit 21 is arranged on the corresponding daughter board 11 of the circuit board assembly 10. Each camera unit 21 comprises a lens 211, a voice coil motor 212, an optical filter 214, and an image sensor 215.

In an alternative embodiment, the camera module 20 comprises two camera units 21.

The lens 211 is received in the voice coil motor 212, and the optical filter 214 and the image sensor 215 are both arranged outside of the voice coil motor 212. The optical filter 214 is arranged between the voice coil motor 212 and the image sensor 215, and is opposite to the lens 211. The image sensor 215 is arranged on the daughter board 11, and is opposite to the lens 211 and the optical filter 214.

The voice coil motor 212 comprises a third surface 2121 and a fourth surface 2122 opposite to the third surface 2121. The voice coil motor 212 defines at least two first receiving holes 2123 through the third surface 2121 and the fourth surface 2122. The lens 211 is received in the first receiving hole 2123. The voice coil motor 212 is configured for driving the lens 211 to move along the optical axes of the lens 211 for automatic focusing.

The camera module 20 further comprises a base 213 arranged on the daughter board 11. The base 213 defines a first surface away from the daughter board 11. The voice coil motor 212 is positioned on the first surface of the base 213. The base 213 is substantially a box, defining at least two light through holes 2131, and defining two circular grooves 2132 adjacent to the light through hole 2131. A portion of the first surface of the base 213 adjacent to the light through hole 2131 is sunken to form the groove 2132. The optical filter 214 is fixed in the circular groove 2132, and is configured to filter the light which is not sensed by the image sensor 215.

The camera module 20 further comprises a bracket 216. The bracket 216 has the structure of a frame, and defines at least two second receiving holes 2161, which are configured for receiving the voice coil motors 212 and the base 213.

In assembling, the voice coil motor 212 is fixed in the upper half part of the second receiving hole 2161 by a first adhesive layer 41, and then the base 213 is fixed in the lower half part of the second receiving hole 2161. The lens 211 is aligned with the optical filter 214, and the optical filter 214 is aligned with the image sensor 215. Finally, the circuit board assembly 10 is fixed by a third adhesive layer 43 below the image sensor 215 to correspond to the optical filter 214 and to the second receiving hole 2161.

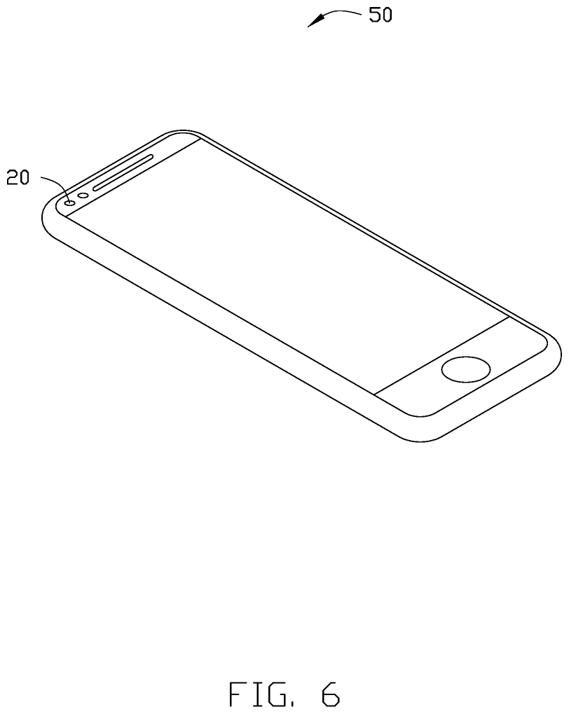

FIG. 6 illustrates an embodiment of an electronic device 50 comprising the camera module 20. The electronic device 50 can be a cellphone, a tablet personal computer, a camera, or an electronic watch with camera function.

The daughter boards 11 are electrically connected to each other by the first flexible printed circuit board 12, avoiding the deformation of the circuit board in the high temperature soldering process, and the production yield is improved.

While the present disclosure has been described with reference to particular embodiments, the description is illustrative of the disclosure and is not to be construed as limiting the disclosure. Therefore, those of ordinary skill in the art can make various modifications to the embodiments without departing from the scope of the disclosure as defined by the appended claims.

What is claimed is:

1. A circuit board assembly comprising:
at least two daughter boards; and
at least one first flexible printed circuit board;
wherein each of the flexible printed circuit board connects adjacent two of the daughter boards.

2. The circuit board assembly of claim 1, wherein the circuit board assembly further comprises a second flexible printed circuit board coupled to a side of the daughter boards, the second flexible printed circuit board is provided with a connector.

3. The circuit board assembly of claim 2, wherein each of the daughter boards has a multilayered structure, each of the first flexible printed circuit board and the second flexible printed circuit boards are both embedded into the daughter boards.

4. The circuit board assembly of claim 3, wherein each of the daughter boards comprises a first hard board layer, a second hard board layer, and a flexible board layer sandwiched between the first hard board layer and the second hard board layer, the first flexible printed circuit board and the second flexible printed circuit board are separately connected to the flexible board layer.

5. The circuit board assembly of claim 1, wherein the circuit board assembly further comprises a reinforcement plate, the reinforcement plate is fixed on surfaces of the at least two daughter boards and the first flexible printed circuit board.

6. A camera module comprising:
a circuit board assembly, comprising:
at least two daughter boards, and
at least one first flexible printed circuit board, each of the flexible printed circuit board connecting adjacent two of the daughter boards; and
at least two camera units, each of the camera units being arranged on the corresponding daughter board.

7. The camera module of claim 6, wherein the circuit board assembly further comprises a second flexible printed circuit board coupled to a side of the at least two daughter boards, the second flexible printed circuit board is provided with a connector.

8. The camera module of claim 7, wherein each of the daughter boards has a multilayered structure, each of the first flexible printed circuit board and the second flexible printed circuit boards are both embedded into the daughter boards.

9. The camera module of claim 8, wherein each of the daughter boards comprises a first hard board layer, a second hard board layer, and a flexible board layer sandwiched between the first hard board layer and the second hard board layer, the first flexible printed circuit board and the second flexible printed circuit board are separately connected to the flexible board layer.

10. The camera module of claim 6, wherein the circuit board assembly further comprises a reinforcement plate, the reinforcement plate is fixed on surfaces of the at least two daughter boards and the first flexible printed circuit board.

11. The camera module of claim 6, wherein each of the camera units comprises:
a voice coil motor;
a lens received in the voice coil motor;
an optical filter; and
an image sensor;
wherein the optical filter and the image sensor are both located outside of the voice coil motor, the optical filter is arranged between the voice coil motor and the image sensor and is opposite to the lens, the image sensor is arranged on the corresponding daughter board and is opposite to the lens and the optical filter.

12. The camera module of claim 11, wherein the camera module further comprises a base arranged on the daughter boards and defining a first surface away from the at least two daughter boards, the voice coil motor is arranged on the first surface of the base.

13. The camera module of claim 12, wherein the base defines at least two light through holes, a portion of the first surface of the base adjacent to one light through hole is sunken to form a groove, the optical filter is fixed in the groove.

14. The camera module of claim 13, wherein the camera module further comprises a bracket arranged on the at least two daughter boards, the bracket defines at least two second receiving hole for receiving the voice coil motor and the base.

15. An electronic device comprising:
a camera module, comprising:
a circuit board assembly, comprising:
at least two daughter boards, and
at least one first flexible printed circuit board, each of the flexible printed circuit board connecting adjacent two of the daughter boards; and
at least two camera units, each of the camera units being arranged on the corresponding daughter board.

16. The electronic device of claim 15, wherein the circuit board assembly further comprises a second flexible printed circuit board coupled to a side of the at least two daughter boards, the second flexible printed circuit board is provided with a connector.

17. The electronic device of claim 16, wherein each of the daughter boards has a multilayered structure, each of the first flexible printed circuit board and the second flexible printed circuit boards are both embedded into the daughter boards.

18. The electronic device of claim 17, wherein each of the daughter boards comprises a first hard board layer, a second hard board layer, and a flexible board layer sandwiched between the first hard board layer and the second hard board layer, the first and second hard board layers are made of materials with high glass transition temperature, the first flexible printed circuit board and the second flexible printed circuit board are separately connected to the flexible board layer.

19. The electronic device of claim 15, wherein the circuit board assembly further comprises a reinforcement plate, the reinforcement plate is fixed on surfaces of the at least two daughter boards and the first flexible printed circuit board.

20. The electronic device of claim 15, wherein each of the camera units comprises:
a voice coil motor;
a lens received in the voice coil motor;
an optical filter; and
an image sensor;
wherein the optical filter and the image sensor are both located outside of the voice coil motor, the optical filter is arranged between the voice coil motor and the image sensor and is opposite to the lens, the image sensor is arranged on the corresponding daughter board and is opposite to the lens and the optical filter.
